(19) United States
(12) Patent Application Publication
(10) Pub. No.: US 2026/0332381 A1
(43) Pub. Date: Oct. 22, 2026

(54) SIGNAL ANALYSIS SYSTEM, DATA STORAGE SYSTEM AND CONTROL DEVICE

(71) Applicant: SK hynix Inc., Icheon-si (KR)

(72) Inventors: Hyun Jun KIM, Icheon-si (KR); Myeong Jin KIM, Icheon-si (KR); Ki Bum KANG, Icheon-si (KR); Jin Hyun KIM, Icheon-si (KR); Gyu Sun PARK, Icheon-si (KR)

(21) Appl. No.: 19/319,285

(22) Filed: Sep. 4, 2025

(30) Foreign Application Priority Data
Apr. 17, 2025 (KR) 10-2025-0049839

(51) Int. Cl. H04L 7/033

(52) U.S. Cl. CPC H04L 7/0337

(57) ABSTRACT

A signal analysis system includes a first analysis analyzer configured to provide measurement data on a change in a test signal based on signals acquired from a first connection point and a second connection point among a plurality of connection points, each of the plurality of connecting points being between a plurality of an adjacent pair of a plurality of cells included in a signal path transmitting the test signal. Such a system further includes a second analyzer configured to generate an analysis signal modified from the test signal based on the measurement data, calculate at least one duty cycle value of the analysis signal, and provide analysis information capable of adjusting a parameter value of at least one cell located between the first connection point and the second connection point based on the at least one duty cycle value.

### CROSS-REFERENCE TO RELATED APPLICATION

The present application claims priority under 35 U.S.C. 119(a) to Korean patent application number 10-2025-0049839 filed on Apr. 17, 2025, which is incorporated herein by reference in its entirety.

### TECHNICAL FIELD

The embodiments of the present disclosure relate to a signal analysis system, a data storage system, and a control device.

### BACKGROUND

A semiconductor device may include a memory chip that stores data, or a control chip that controls the operation of the memory chip. A semiconductor device such as a memory chip or a control chip may include a signal path that transmits various types of signals (e.g., a clock signal or a data signal).

A signal transmitted through a signal path may be distorted due to internal or external factors in the signal path included in the semiconductor device. The operating performance of the semiconductor device may be deteriorated due to the distortion of the signal.

### SUMMARY

The tasks of embodiments of the present disclosure are not limited to the tasks mentioned in this disclosure, and other tasks not mentioned may be understood by those skilled in the art from the description below.

Embodiments of the disclosure may provide a method capable of easily analyzing a distortion of a signal transmitted through various signal paths included in a semiconductor device and improving signal transmission performance by setting parameter values for the signal paths.

Embodiments of the disclosure may provide a signal analysis system including a first analyzer configured to provide measurement data on a change in a test signal based on signals acquired from a first connection point and a second connection point among a plurality of connection points, each of the plurality of connecting points being between an adjacent pair of a plurality of cells included in a signal path transmitting the test signal, and a second analyzer configured to generate an analysis signal modified from the test signal based on the measurement data, calculate at least one duty cycle value of the analysis signal, and provide analysis information capable of adjusting a parameter value of at least one cell located between the first connection point and the second connection point based on the at least one duty cycle value.

Embodiments of the disclosure may provide a data storage system including a memory device, and a control device configured to control the memory device, and adjust at least one first parameter value of at least one cell located between a first connection point and a second connection point based on signals acquired from the first connection point and the second connection point among a plurality of first connection points, each of the plurality of first connecting points being between an adjacent pair of a plurality of first cells included in a first signal path through which a clock signal is transmitted.

Embodiments of the disclosure may provide a control device including a control circuit configured to control a memory device located outside of the control circuit, a first signal path including a plurality of first cells and transmitting a first type of signal, a first parameter value of at least first one of the plurality of first cells being different from a second parameter value of at least second one of the plurality of first cells, each of the first and second parameter values indicating at least one of an input voltage to a corresponding one of the plurality of first cells or a ratio of the input voltage to an output voltage from the corresponding one of the plurality of first cells, and a second signal path including a plurality of second cells and transmitting a second type of signal different from the first type signal.

According to embodiments of the present disclosure, it is possible to easily adjust a signal distortion by analyzing signal distortion for each cell in a signal path included in a semiconductor device and setting parameter values for each cell.

The effects of the embodiments of the present disclosure are not limited to the described effects, and other effects not mentioned may be understood by those skilled in the art in light of teachings of the present disclosure.

### BRIEF DESCRIPTION OF THE DRAWINGS

Embodiments of the present disclosure will be more fully understood from the detailed description and accompanying drawings provided below, which are provided for illustration purposes only and are not intended to limit various embodiments of the present disclosure.

FIG. 1 illustrates a schematic configuration of a signal analysis system according to embodiments of the present disclosure.

FIG. 2 illustrates a function performed by each component included in a signal analysis system according to embodiments of the present disclosure.

FIG. 3 illustrates information measured and provided from a semiconductor device by a signal analysis system according to embodiments of the present disclosure.

FIG. 4 illustrates analysis performed on a signal path of a semiconductor device by a signal analysis system according to embodiments of the present disclosure.

FIG. 5, FIG. 6, and FIG. 7 illustrate analysis information provided by a signal analysis system according to embodiments of the present disclosure.

FIG. 8 illustrates a process of a signal analysis method according to embodiments of the present disclosure.

FIG. 9 illustrates a data storage system including a signal analysis function according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise. As used herein, “at least one of . . . or” indicates a disjunctive list of each of items as well as possible combination(s). For example, “at least one of A or B” indicates “only A, or only B, or both A and B,” and “at least one of A, B, or C” indicates “only A, or only B, only C, or both A and B, or both A and C, or both B and C, or all of A and B and C,” and so on.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to,” or “contacts or overlaps” a second element, it should be interpreted that, not only can the first element “be directly connected or coupled to” or “directly contact or overlap” the second element, but a third element can also be “interposed” between the first and second elements, or the first and second elements can “be connected or coupled to,” or “contact or overlap” each other via a fourth element. Here, the second element may be included in at least one of two or more elements that “are connected or coupled to,” or “contact or overlap.”

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the present disclosure will be described in detail with reference to accompanying drawings.

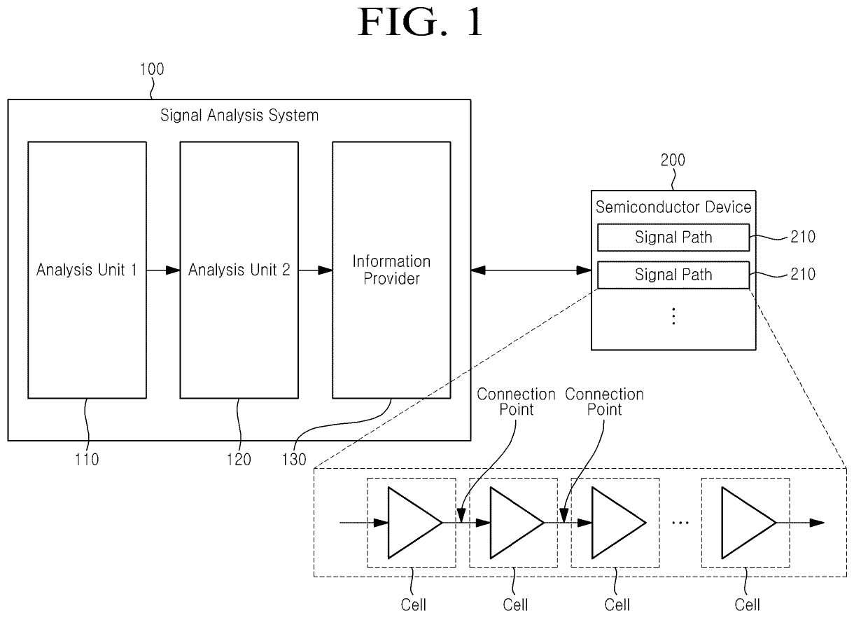

FIG. 1 illustrates a schematic configuration of a signal analysis system 100 according to embodiments of the present disclosure.

Referring to FIG. 1, the signal analysis system 100 according to embodiments of the present disclosure may include, for example, a first analysis unit (or a first analyzer) 110, a second analysis unit (or a second analyzer) 120, and an information provider 130. Specifically, the first analyzer 110 and the second analyzer 120 each may be implemented by hardware (e.g., first and second analysis circuits, respectively), or software, or both. When implemented at least partially in software, each of the first and second analyzers 110 and 120 may include a storage device for storing code or instructions to be executed, for example, by a computer, processor, microprocessor, controller, or other signal processing device. The signal analysis system 100 may analyze a signal transmitted from inside an electronic device and provide analysis information required to correct distortion of the signal. In some cases, the signal analysis system 100 may analyze a signal transmitted from inside to outside of an electronic device or transmitted from outside to inside of an electronic device and provide analysis information.

The signal analysis system 100 may analyze a signal transmitted in a semiconductor device 200 and provide analysis information, for example.

The semiconductor device 200 may be, for example, a memory that stores data. In addition, the semiconductor device 200 may be a non-memory. The semiconductor device 200 may be a controller that controls the operation of the memory, or a processor that performs a computational function. In addition, in some cases, the semiconductor device 200 may be a memory or a controller that includes a computational function. The semiconductor device 200 is not limited to the above-described examples, and may be various semiconductor devices that include a path through which a signal is transmitted internally, and may be one of the devices on which signal analysis can be performed by the signal analysis system 100 according to embodiments of the present disclosure.

The semiconductor device 200 may include at least one signal path 210 internally. The signal path 210 may refer to a path through which a signal required for the operation of the semiconductor device 200 is transmitted. In some embodiments, the signal path 210 may be a path through which at least one of a clock signal or a data signal is transmitted in a controller that controls a memory. The signal path 210 may refer to, for example, a path through which a clock signal is transmitted. In addition, the signal path 210 may refer to a path through which a data signal is transmitted. Data may be transmitted through the signal path 210, or a command for controlling an operation may be transmitted. In some cases, the path may mean a path through which a voltage for the operation of the semiconductor device 200 is transmitted.

In addition, the signal path 210 in FIG. 1 illustrates a case in which a signal is transmitted inside the semiconductor device 200, but may also include a path through which a signal is transmitted from the inside of the semiconductor device 200 to the outside, or a path through which a signal is transmitted from the outside of the semiconductor device 200 to the inside of the semiconductor device 200.

The signal path 210 may include, for example, a plurality of cells. Each of the plurality of cells may include at least one transistor. A signal may be input to each of the plurality of cells, and a signal may be output through the cell. A plurality of cells may constitute the signal path 210, and a signal may be transmitted through the plurality of cells.

A point at which a signal is transmitted between the plurality of cells may be referred to as a connection point. A signal output from each of the plurality of cells may be transmitted to another cell through a connection point. The signal analysis system 100 may acquire a signal from a connection point located between the plurality of cells and provide a result of analyzing the signal.

As an example, the first analysis unit 110 may acquire a signal from at least one connection point between the plurality of cells. The first analysis unit 110 may provide measurement data based on the acquired signal. The first analysis unit 110 may acquire signals from two or more connection points. At least one cell may be located between two or more connection points from which a signal is obtained by the first analysis unit 110.

As an example, the first analysis unit 110 may obtain a signal from connection points corresponding to both ends of the plurality of cells, or may obtain a signal from connection points corresponding to both ends of a single cell. Since the first analysis unit 110 obtains signals from various connection points and provides measurement data, signal analysis can be performed on a cell basis included in the signal path 210.

The measurement data provided by the first analysis unit 110 may be data capable of confirming a transformation or a distortion of the signal. For example, a test signal may be transmitted through the signal path 210 included in the semiconductor device 200. The first analysis unit 110 may obtain signals from two or more connection points included in the signal path 210. The first analysis unit 110 may provide measurement data regarding a change in signal level (e.g., IR Drop) based on signals obtained from two or more connection points, for example. The first analysis unit 110 may provide measurement data regarding jitter of the signal. In addition, the first analysis unit 110 may provide various measurement data regarding physical changes in the test signal. For example, the first analysis unit 110 may provide voltage change data (e.g., voltage drop data) and jitter data of the test signal for each of a plurality of cycles.

The second analysis unit 120 may analyze the degree of distortion of the test signal based on the measurement data provided by the first analysis unit 110. For example, the second analysis unit 120 may generate an analysis signal based on the measurement data provided from the first analysis unit 110. The analysis signal may be a signal reflecting the degree of distortion of the test signal.

The second analysis unit 120 may generate an analysis signal using, for example, phase delay data, or jitter data, or both, as the measurement data provided from the first analysis unit 110. The second analysis unit 120 may generate an analysis signal using the phase delay data, jitter data, and a reference signal period. The reference signal period may mean a time corresponding to a cycle of the test signal.

The second analysis unit 120 may receive one or both of phase delay data and jitter data from the first analysis unit 110. The second analysis unit 120 may obtain (e.g., extract) phase delay data, or jitter data, or both from the measurement data received from the first analysis unit 110. In some embodiments, the second analysis unit 120 may extract first phase delay data between first edges (e.g., rising edges) of the test signal and second phase delay data between second edges (e.g., falling edges) of the test signal based on the measurement data. Depending on the format of the measurement data received from the first analysis unit 110, the second analysis unit 120 may use the measurement data directly or may extract the measurement data to use.

The second analysis unit 120 may generate an analysis signal for each section of the test signal in order to generate an analysis signal and analyze the degree of distortion of the test signal. For example, the second analysis unit 120 may generate a first analysis signal and a second analysis signal.

The first analysis signal may be a signal generated for a section in which the level of the test signal changes from a first level to a second level and changes from the second level to the first level. For example, the first level may be a high level and the second level may be a low level. Alternatively, the first level may be a low level and the first level may be a high level.

The second analysis signal may be a signal generated for a section in which the level of the test signal changes from the second level to the first level and changes from the first level to the second level.

The second analysis unit 120 may provide analysis information that may indicate the degree of distortion of the test signal by using the first analysis signal and the second analysis signal.

The second analysis unit 120 may calculate a first duty cycle value in a portion where the level of the test signal changes from the first level to the second level based on the first analysis signal. The second analysis unit 120 may calculate a second duty cycle value in a portion where the level of the test signal changes from the second level to the first level based on the first analysis signal. The duty cycle value may indicate a value according to a ratio of the first level to the second level in each cycle of the signal.

In addition, the second analysis unit 120 may calculate a third duty cycle value in a portion where the level of the test signal changes from the second level to the first level based on the second analysis signal. The second analysis unit 120 may calculate a fourth duty cycle value in a portion where the level of the test signal changes from the first level to the second level based on the second analysis signal.

The second analysis unit 120 may calculate a duty cycle value for each portion of the test signal to identify a portion where the degree of distortion of the test signal is the greatest. For example, the second analysis unit 120 may identify a portion in which the difference in the ratio between a duration of the test signal having the first level and a duration of the test signal having the second level is the greatest based on the duty cycle value. In addition, there may be identified that the degree of distortion of the test signal is the greatest in the corresponding portion. The second analysis unit 120 may provide analysis information on a portion indicating the greatest degree of distortion of the test signal. The distortion of the test signal can be corrected based on the analysis information. In some embodiments, the second analysis unit 120 may provide, as analysis information, at least one duty cycle value in a range other than a preset threshold range among the first duty cycle value, the second duty cycle value, the third duty cycle value, and the fourth duty cycle value that are calculated as described above. In some embodiments, the second analysis unit 120 may provide information about a cycle of the analysis signal, phase delay data, and jitter data corresponding to the at least one duty cycle value, as the analysis information. In some embodiments, the second analysis unit 120 provides test termination information, if the analysis signal is different from the test signal and the at least one duty cycle value of the analysis signal is within a preset threshold range. The preset threshold range may be determined (or configured) based on a variation or a distortion of the test signal. If the test signal is not recognized by a degree of the variation or the distortion of the test signal, the degree may be a base to configure the preset threshold range. The preset threshold range may be a range that the test signal is recognized same or similarly at one point and the other point.

The information provider 130 may provide analysis information produced by the second analysis unit 120. The information provider 130 may provide information that can identify the degree of distortion of the test signal and the portion in which the distortion is severe among the analysis information produced by the second analysis unit 120.

In addition, the information provider 130 may provide at least a part of the measurement data used for generating an analysis signal and providing analysis information by the second analysis unit 120. The information provider 130 may provide at least a part of the information in a visualized form. The analysis and adjustment of the signal path 210 in the semiconductor device 200 may be performed based on the analysis information provided by the information provider 130.

The signal analysis system 100 may provide analysis information on the signal path (e.g., a first signal path) 210 through which a first type of signal is transmitted in the semiconductor device 200. Based on the analysis information provided by the signal analysis system 100, it is possible to adjust at least one parameter value of a plurality of cells included in the signal path 210 through which the first type of signal is transmitted in the semiconductor device 200. The parameter value of the cell may be, for example, a value for setting a voltage input to the cell. Alternatively, the parameter value of the cell may be a value for setting a ratio of a voltage input to a cell and the voltage output from a cell. The parameter value of the cell may mean at least one of various setting values capable of adjusting the signal or voltage input to or output from the corresponding cell.

The signal analysis system 100 may provide analysis information on a signal path (e.g., a second signal path) 210 through which a second type of signal is transmitted in the semiconductor device 200. At least one parameter value of a plurality of cells included in the signal path 210 through which a second type of signal is transmitted in the semiconductor device 200 may be adjusted based on the analysis information.

Alternatively, the signal analysis system 100 may provide analysis information on a signal path 210 through which a first type of signal is transmitted in the semiconductor device 200. At least one parameter value of a plurality of cells included in the signal path 210 transmitting a first type of signal may be adjusted based on the analysis information. In addition, at least one parameter value of a plurality of cells included in the signal path 210 transmitting a second type of signal may be adjusted based on the analysis information.

The first type of signal may be, for example, a clock signal, and the second type of signal may be a data signal, but the embodiments of the present disclosure are not limited thereto.

Examples of specific functions performed by the signal analysis system 100 and analysis information provided may be as follows.

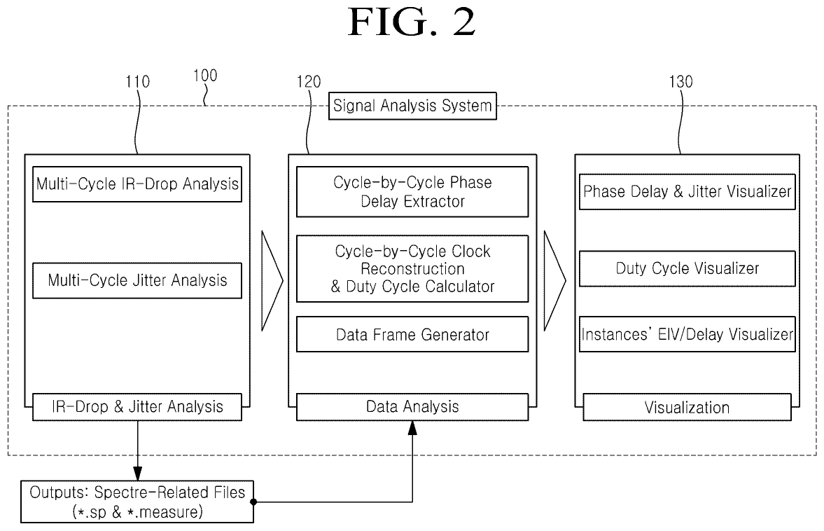

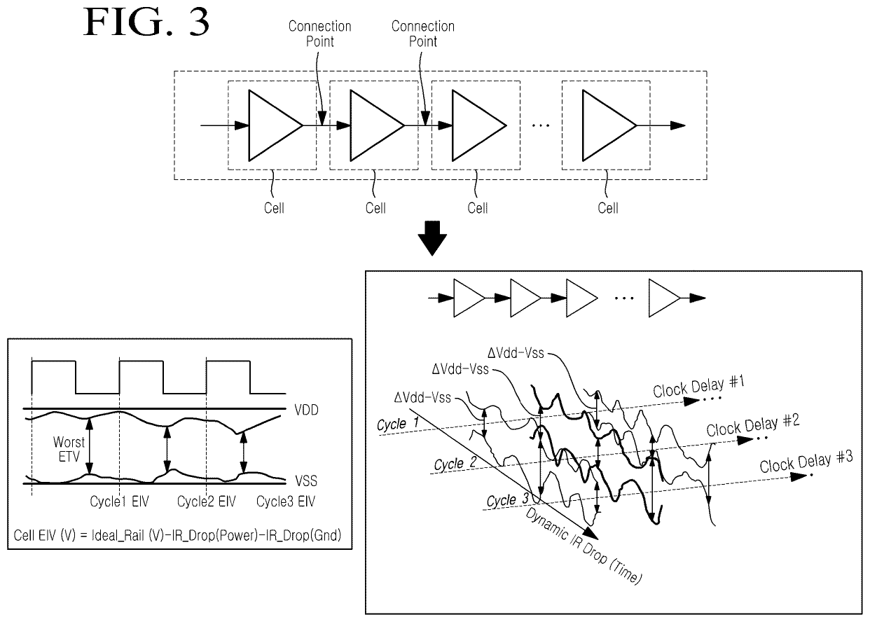

FIG. 2 illustrates functions performed by each component included in the signal analysis system 100 according to embodiments of the present disclosure. FIG. 3 illustrates information measured and provided from a semiconductor device 200 by the signal analysis system 100 according to embodiments of the present disclosure.

Referring to FIGS. 2 and 3, the first analysis unit (or the first analyzer) 110 of the signal analysis system 100 may analyze voltage drops and jitters for a plurality of cycles of a test signal transmitted through a signal path 210 composed of a plurality of cells in the semiconductor device 200 and provide measurement data. FIG. 3 illustrates a case where the test signal is a clock signal.

The signal transmitted through the plurality of cells included in the signal path 210 may be, for example, a signal generated by a voltage VDD and a voltage VSS. Voltage VDD may be, for example, a relatively high potential voltage, and voltage VSS may be a relatively low potential voltage.

Voltage drop and jitter may be measured in each cycle of the test signal. Effective instance voltage EIV, which is determined by the smallest difference between the high potential voltage and the low potential voltage according to the voltage drop, may be measured.

In addition, a degree of delay of the test signal may be measured according to the measurement result of the test signal in each cycle.

The first analysis unit 110 may provide measurement information on a voltage drop, a phase delay, or an effective instance voltage for each cycle based on signals obtained from connection points between a plurality of cells included in the signal path 210.

The second analysis unit (or the second analyzer) 120 may generate an analysis signal based on measurement data provided by the first analysis unit 110. A file format of the measurement data provided by the first analysis unit 110 may vary depending on a measuring system. For example, as in the example illustrated in FIG. 2, measurement data may be provided in the form of *.sp, *.measure to the second analysis unit 120.

The second analysis unit 120 may extract a phase delay from the measurement data in unit of cycle. The second analysis unit 120 may generate an analysis signal in which a test signal is modified based on the extracted phase delay data, the received jitter data, and the reference signal period. The analysis signal may be generated in various ways according to a section in which the signal level changes, as in the example described above.

The second analysis unit 120 may generate an analysis signal, and calculate a duty cycle value for each section of the analysis signal to generate analysis information for identifying the degree of distortion of the test signal. In addition, the second analysis unit 120 may generate a data frame for providing information on the generated analysis signal and information used to generate the analysis signal.

The analysis information generated by the second analysis unit 120 may be provided through the information provider 130, and in some cases, the analysis information may be provided in a visualized form.

The information provider 130 may provide visualization of the phase delay data and the jitter data measured and provided by the first analysis unit 110. The information provider 130 may provide visualization of duty cycle values based on analysis signals generated by the second analysis unit 120. The information provider 130 may provide visualization of information on the delay of the effective instance voltage and signal generated according to the analysis results of the second analysis unit 120.

Since the signal analysis system 100 provides signal analysis results in units of a plurality of cells included in the signal path 210 of the semiconductor device 200, it is possible to perform the signal distortion adjustment in units of each cell of the signal path 210.

The signal analysis system 100 may perform measurement and analysis in units of cells, or may perform measurement and analysis in units of a certain range, and may change the measurement point according to the measurement and analysis results to provide analysis information.

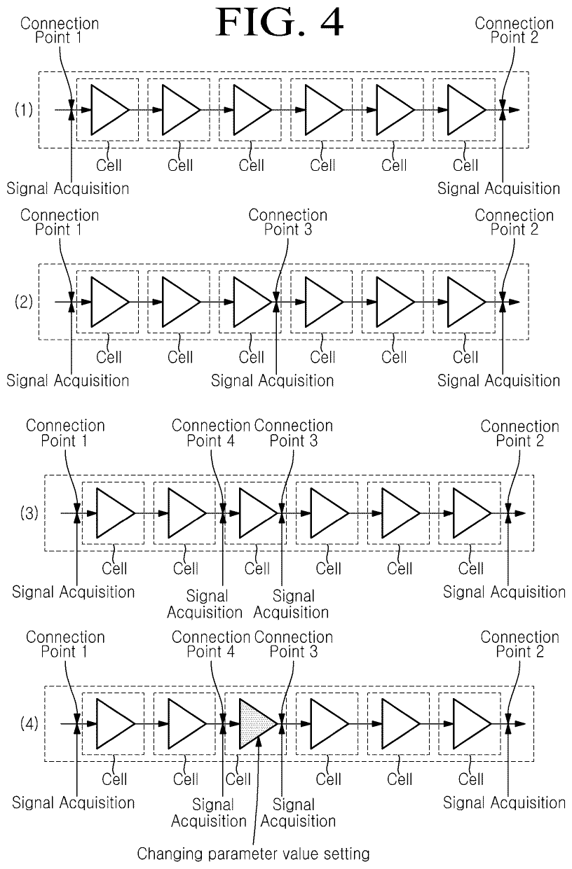

FIG. 4 illustrates a signal analysis system 100 performing analysis on a signal path 210 of a semiconductor device 200, according to embodiments of the present disclosure.

Referring to FIG. 4, as in the example shown in (1), the signal analysis system 100 may acquire signals from both ends of a plurality of cells included in the signal path 210. The example shown in (1) of FIG. 4 illustrates a case where six cells are arranged, but there may vary the number of cells located between connection points where signals are obtained.

The signal analysis system 100 may obtain signals from a first connection point and a second connection point. The signal analysis system 100 may compare a signal acquired from the first connection point with a signal acquired from the second connection point to measure the degree of distortion of the signal acquired from the second connection point. Alternatively, the signal analysis system 100 may measure the degree of distortion of the signal acquired at the second connection point by comparing the signal acquired at the second connection point to the test signal transmitted through the signal path 210.

A method of acquiring or measuring a signal by the signal analysis system 100 at a connection point between a plurality of cells included in the signal path 210 to measure the degree of distortion of the test signal may vary according to embodiments, and the signal may be acquired at a point necessary to measure an occurrence of the distortion of the test signal and the degree of distortion.

If the degree of distortion of the test signal is greater than a threshold range or threshold value set between the first connection point and the second connection point based on the analysis result of the signal acquired at the first connection point and the signal acquired at the second connection point, the signal analysis system 100 may measure a signal at one or more connection points between the first connection point and the second connection point.

For example, as in the example illustrated in (2), the signal analysis system 100 may measure a signal at a third connection point located between the first connection point and the second connection point. The signal analysis system 100 may analyze, based on the analysis result of the signal measured at the third connection point, an occurrence of the distortion of the test signal between the first connection point and the third connection point or between the third connection point and the second connection point.

The signal analysis system 100 may measure a signal at an additional connection point according to the analysis result of the section where the distortion of the test signal occurs.

For example, as in the example illustrated in (3), the signal analysis system 100 may measure a signal at a fourth connection point. The fourth connection point may be located between the first connection point and the third connection point. If a distortion or a distortion of the test signal occurs between the first connection point and the third connection point, or if it is analyzed that a distortion of the test signal occurs significantly in the corresponding section, signal measurement may be performed at the fourth connection point located between the first connection point and the third connection point.

The signal analysis system 100 may identify a cell in which a test signal distortion occurs transmitted through the signal path 210 based on the signal measured at the fourth connection point. For example, it may be identified that a test signal distortion occurs in a cell located between the third connection point and the fourth connection point in the signal path 210 according to the analysis process described above.

The parameter value setting for at least one cell among the plurality of cells included in the signal path 210 may be changed or adjusted according to the analysis result of the signal analysis system 100.

For example, as in the example illustrated in (4), the parameter value setting for a cell located between the third connection point and the fourth connection point may be changed or adjusted. A level of an input voltage to the cell, a ratio of the input voltage to an output voltage from the cell, or the characteristic value of a transistor disposed in the cell may be changed or adjusted. The size, number, and so on of the transistor(s) disposed in the cell may be adjusted differently from other cells.

The parameter value setting for at least one cell among a plurality of cells included in the signal path 210 may be different from the parameter value setting for the remaining cells by cell-by-cell adjustment according to the signal analysis result.

Signal measurement and analysis may be performed on each signal path 210, and the parameter value for the cell included in each signal path 210 may be adjusted accordingly. In addition, in some embodiments, based on the analysis result for a first signal path 210 transmitting a first type of signal, the parameter value for the cell included in a second signal path 210 transmitting a second type of signal may also be adjusted, where the second type of signal is different from the first type of signal.

The signal may be measured in cell units, the analysis signal may be reconstructed according to the measurement, and the cell causing the signal distortion may be easily analyzed based on the reconstructed analysis signal. The cell-by-cell adjustments may be performed based on the analysis results, thereby preventing or reducing a degradation of performance of the semiconductor device 200 due to variations such as jitter of a signal transmitted through a signal path 210.

The signal analysis system 100 may analyze a signal in units of cells, and may provide analysis information in a visualized manner so that parameter values can be adjusted based on the analyzed results.

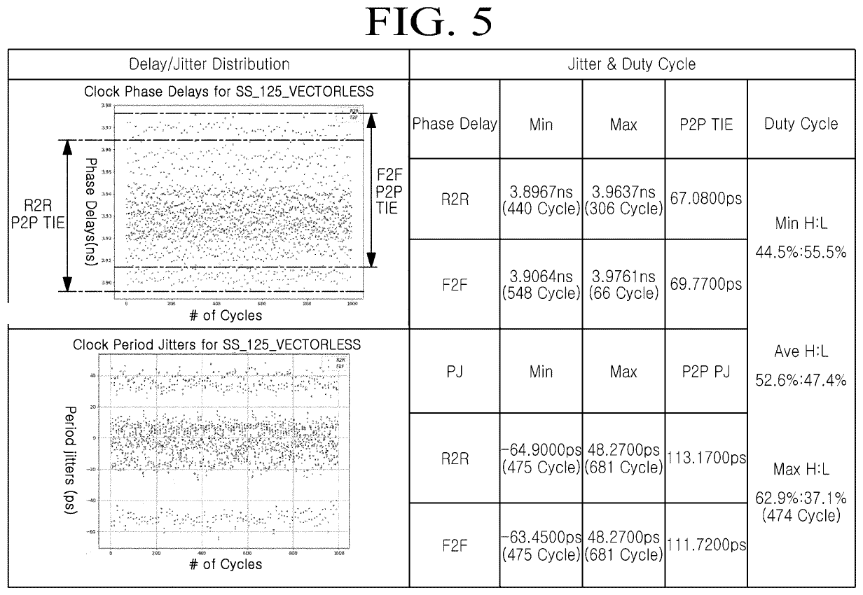

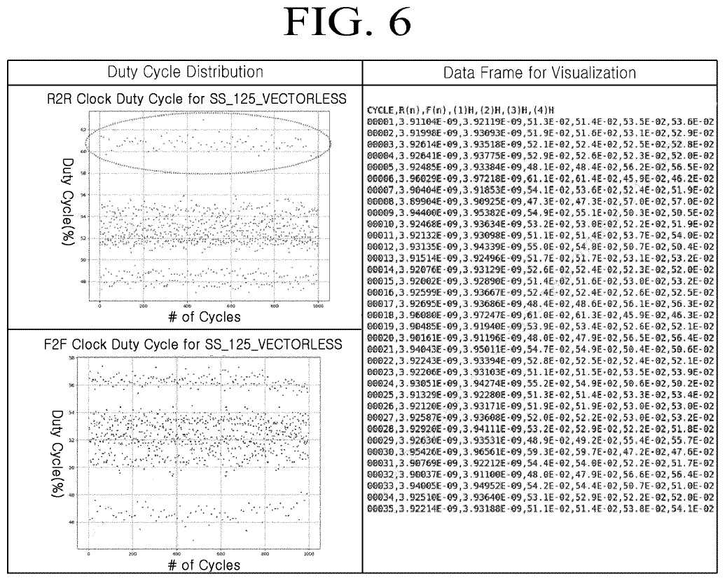

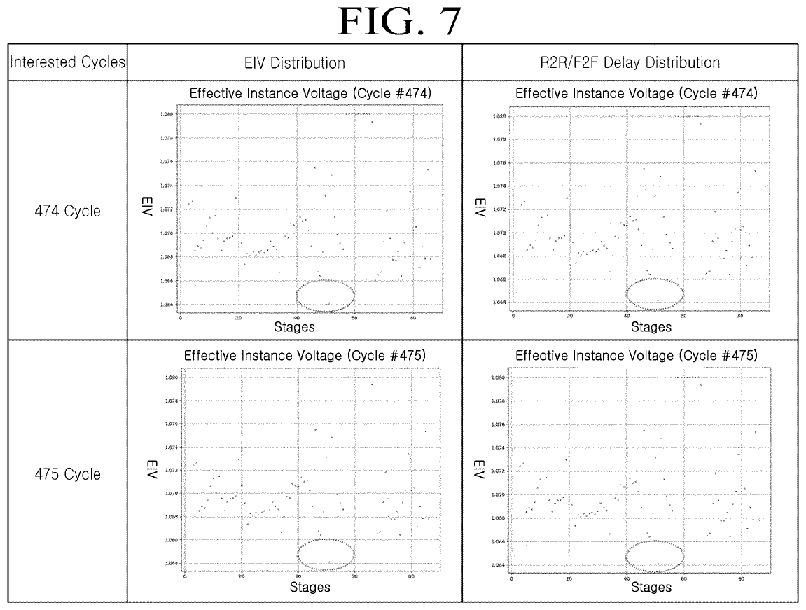

FIGS. 5 to 7 illustrate examples of analysis information provided by the signal analysis system 100 according to embodiments of the present disclosure.

Referring to FIG. 5, it is illustrated an example in which the signal analysis system 100 provides phase delay, phase jitter (PJ), and duty cycle values of a test signal. The signal analysis system 100 may provide phase delay data between first edges (e.g., rising edges) and phase delay data between second edges (e.g., falling edges) of a test signal through signal measurement in units of cells included in a signal path 210 of a semiconductor device 200.

The signal analysis system 100 may provide minimum value and/or maximum value of phase delay data between rising edges in an acquired signal. The signal analysis system 100 may provide the minimum value and/or maximum value of the phase delay data between the falling edges in the acquired signal.

In addition, the signal analysis system 100 may provide the minimum value and/or maximum value of the jitter data between the rising edges in the acquired signal. The signal analysis system 100 may provide the minimum value and/or maximum value of the jitter data between the falling edges in the acquired signal.

The signal analysis system 100 may provide a duty cycle value calculated based on the generated analysis signal. The duty cycle value may be provided as a ratio between a duration when the signal is at the first level and a duration when the signal is at the second level in each section of the analysis signal. One of the first level and the second level may be a high level, and the other may be a low level. The signal analysis system 100 may provide analysis information on a cycle where a difference in the ratio between the duration when the signal is at the first level and the duration when the signal is at the second level is the largest in the duty cycle value. Information about a cell for which a parameter value setting change is required may be provided based on a duty cycle value.

The signal analysis system 100 may provide information on a visualized distribution of duty cycle values. For example, as in the example illustrated in FIG. 6, the signal analysis system 100 may provide a visualized distribution of duty cycle values in each cycle according to an interval between rising edges. The signal analysis system 100 may provide a visualized distribution of duty cycle values in each cycle according to an interval between falling edges.

A duty cycle value that falls outside a specific range can be identified in the distribution of duty cycle values. The signal analysis system 100 may provide analysis information about a case where a duty cycle value falls outside an allowable range based on a preset threshold range or threshold value. Information about a cell for which a parameter value setting change is required may be provided based on the analysis information provided visually.

The signal analysis system 100 may provide various analysis information in a visualized manner so that the duty cycle value can be improved in the corresponding cycle if the duty cycle value is out of the threshold range. For example, as shown in the example of FIG. 7, the signal analysis system 100 may provide information of a visualized form about the distribution of the effective instance voltage or the distribution of the delay data in a cycle 474 and a cycle 475. The delay data can include the delay data in the interval between rising edges or the delay data in the interval between falling edges.

Since information on the distribution of the effective instance voltage or the distribution of the delay data is provided in each cycle, it is possible to identify or select a cell, among the cells included in the signal path 210, that requires a change in the setting of the parameter value based on the analysis information.

Since the signal analysis system 100 measures signals in units of cells included in the signal path 210 of the semiconductor device 200 and provides analysis information based on the measurement data by visualization form, signal distortion according to the signal path 210 can be easily corrected by changing the setting of parameter values in units of cells.

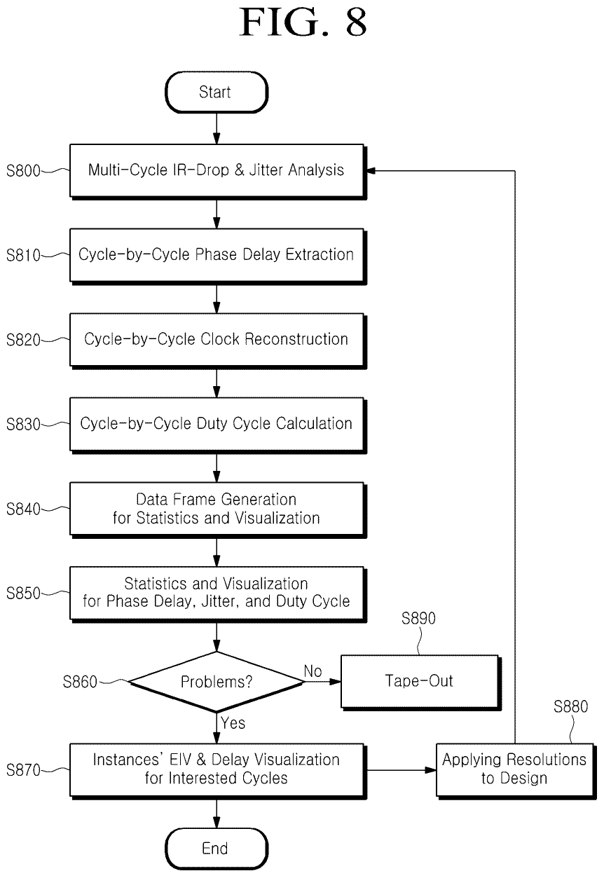

FIG. 8 illustrates a signal analysis method according to embodiments of the present disclosure.

Referring to FIG. 8, the signal analysis method may be performed by the signal analysis system 100, and in some cases, may be performed by a configuration included in a device through which the corresponding signal is transmitted.

If the signal analysis method is performed by the signal analysis system 100 as an example, the signal analysis system 100 may analyze a voltage drop and jitter for a plurality of cycles by measuring signals in units of cells in the signal path 210 included in the semiconductor device 200 (S800).

The signal analysis system 100 may extract phase delay data from measurement data regarding voltage drop and jitter (S810). In some cases, the signal analysis system 100 may also receive phase delay data as measurement data.

The signal analysis system 100 may generate an analysis signal in units of cycles by using phase delay data and jitter data acquired through signal measurement, and using a reference signal period of a test signal (S820). If the test signal is a clock signal, the signal analysis system 100 may reconstruct the clock signal and provide the reconstructed clock signal as an analysis signal.

The signal analysis system 100 may calculate a duty cycle value in units of cycles based on the generated analysis signal (S830).

The signal analysis system 100 may generate a data frame for statistics and visualization (S840), and may provide statistics and visualization information on phase delay data, jitter data, and duty cycle values as analysis information (S850).

If it is determined that there is a problem in the signal path 210 (S860) the signal analysis system 100 can provide visualized effective instance voltage and delay data for a cycle with a large (or severe) degree of signal distortion based on the provided analysis information (S870). A parameter value setting change for at least one of the plurality of cells included in the signal path 210 based on the visualized analysis information may be performed (S880).

If it is determined that there is no problem according to the analysis information, the signal analysis process may be terminated without changing the parameter value setting for the cell included in the signal path 210 (S890).

It is possible to easily perform a correction for signal distortion of the semiconductor device 200 using cell-by-cell analysis of the signal path 210 by the signal analysis system 100. Since such a semiconductor device 200 for which signal distortion correction can be performed is provided, it is possible to improve the operating performance of an electronic device including the semiconductor device 200.

In some cases, the signal analysis and the operation of changing the parameter value setting may be performed by the semiconductor device 200, such as a control chip performing a control function.

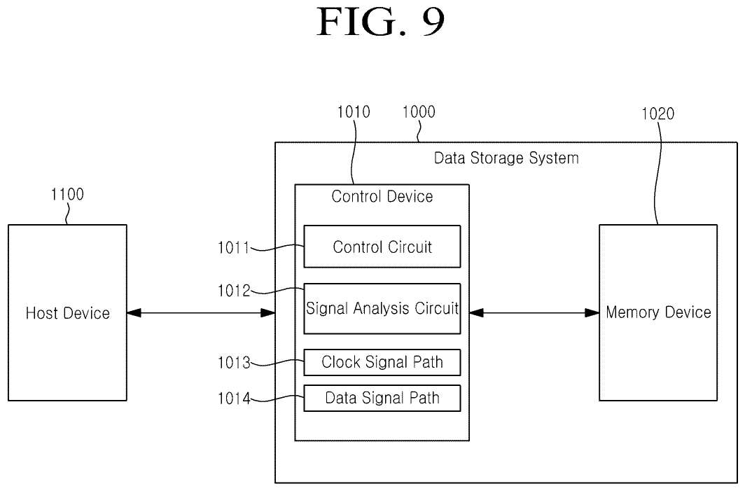

FIG. 9 illustrates a data storage system 1000 including a signal analysis function according to embodiments of the present disclosure.

Referring to FIG. 9, a data storage system 1000 may include a memory device 1020 and a control device 1010. The data storage system 1000 may perform an operation according to a request or command of a host device 1100. The host device 1100 may be, for example, a processor, and may be one of various electronic devices that store various data using the data storage system 1000.

The memory device 1020 may be, for example, a volatile memory or a nonvolatile memory. A part of the memory devices 1020 included in the data storage system 1020 may be volatile memories, and others may be nonvolatile memories. The volatile memory included in the data storage system 1020 may be a main memory, and in some cases, the volatile memory may be a memory used to control the operation of the nonvolatile memory. In the embodiment of FIG. 9, the memory device 1020 is located outside of the control circuit 1010, but embodiments of the present disclosure are not limited thereto.

The control device 1010 may control the operation of the memory device 1020. The control device 1010 may control the operation of the memory device 1020 according to the command of the host device 1100. The control device 1010 may also control the operation of the memory device 1020 based on an internal command, in some cases, to improve the performance of the memory device 1020.

The control device 1010 may include, for example, a control circuit 1011. The control circuit 1011 may control the operation of the memory device 1020. The control device 1010 may include a signal analysis circuit 1012. The signal analysis circuit 1012 may perform signal analysis on a path through which a signal is transmitted in the control device 1010.

For example, the control device 1010 may include a clock signal path 1013 and a data signal path 1014. The clock signal path 1013 may be a path through which a clock signal is transmitted. The clock signal path 1013 may include a plurality of cells. The data signal path 1014 may be a path through which a signal such as data or a command is transmitted. The data signal path 1014 may include a plurality of cells.

The signal analysis circuit 1012 may measure one or more signals at one or more connection points between a plurality of cells included in the clock signal path 1013 or the data signal path 1014. The signal analysis circuit 1012 may generate an analysis signal based on the acquired signals. The analysis signal may be a modified signal or a deformed signal of a test signal transmitted through the clock signal path 1013 or the data signal path 1014.

The signal analysis circuit 1012 may generate an analysis signal for a portion in which a test signal changes from a first level to a second level and a portion in which a test signal changes from a second level to a first level. The signal analysis circuit 1012 may generate an analysis signal for a portion in which a test signal changes from a second level to a first level and a portion in which a test signal changes from a first level to a second level.

The signal analysis circuit 1012 may calculate a duty cycle value in each portion using the analysis signal. The signal analysis circuit 1012 may select at least one cell based on the calculated duty cycle value. The signal analysis circuit 1012 may detect a portion in which the degree of distortion of the test signal is outside a preset threshold range or has the greatest degree of distortion based on the duty cycle value.

The signal analysis circuit 1012 may change or adjust the setting of at least one parameter value of one or more cells included in the clock signal path 1013 or the data signal path 1014 according to the analysis result based on the duty cycle value.

As an example, the signal analysis circuit 1012 may change or adjust the setting of the parameter value of at least one cell included in the clock signal path 1013 according to analysis information based on a signal acquired from a connection point between a plurality of cells included in the clock signal path 1013. In some embodiments, the signal analysis circuit 1012 may adjust a parameter value of at least one cell located between a first connection point and a second connection point based on signals acquired from the first connection point and the second connection point among a plurality of first connection points, where each of the plurality of first connecting points is between an adjacent pair of a plurality of first cells included in the clock signal path 1013. For example, the signal analysis circuit 1012 may adjust at least one of an input voltage to the at least one cell or a ratio of the input voltage to an output voltage from the at least one cell.

The signal analysis circuit 1012 may change or adjust the setting of the parameter value of at least one cell included in the data signal path 1014 according to analysis information based on a signal acquired from a connection point between a plurality of cells included in the data signal path 1014. For example, the signal analysis circuit 1012 may adjusts a parameter value of at least one cell located between a third connection point and a fourth connection point based on signals obtained from the third connection point and the fourth connection point among a plurality of second connection points, where each of the plurality of second connecting points is between an adjacent pair of a plurality of second cells included in the data signal path 1014. In some cases, the signal analysis circuit 1012 may also change or adjust the setting of the parameter value of at least one cell included in the data signal path 1014 according to analysis information based on a signal acquired from a connection point between a plurality of cells included in the clock signal path 1013.

The signal analysis circuit 1012 may change or adjust the setting of the parameter value of at least one cell included in the path through which various signals are transmitted and included in the control device 1010. The parameter value of at least one cell included in the clock signal path 1013 may be different from the parameter value of at least one other cell included in the clock signal path 1013. For example, each of the parameter values of a plurality of cells included in the clock signal path 1013 may indicate at least one of an input voltage to a corresponding one of the plurality of cells or a ratio of the input voltage to an output voltage from the corresponding one of the plurality of cells. The parameter value of at least one cell included in the data signal path 1014 may be different from the parameter value of at least one other cell included in the data signal path 1014. For example, each of the parameter values of a plurality of cells included in the data signal path 1014 may indicate at least one of an input voltage to a corresponding one of the plurality of cells or a ratio of the input voltage to an output voltage from the corresponding one of the plurality of cells. In some embodiments, each of the parameter values of a plurality of cells included in the clock signal path 1013 or the data signal path 1014 may be set to be equal. In some embodiments, each of the parameter values of a plurality of cells included in the clock signal path 1013 or the data signal path 1014 may be set to be constant.

In some cases, the path of the corresponding signal may be reconstructed by using at least one redundancy cell included in the control device 1010 without changing the parameter value of the cell. For example, the control device 1010 may include a plurality of redundancy cells respectively corresponding to a plurality of cells included in the clock signal path 1013 or the data signal path 1014. The clock signal path 1013 or the data signal path 1014 may include at least one of the plurality of redundancy cells configured to replace at least one the plurality of cells therein. The cell included in the clock signal path 1013 or the data signal path 1014 may have a structure in which the cell is connected through a redundancy cell. By changing the parameter value of the cell causing signal delay, jitter, or distortion, or by replacing the cell with a redundancy cell, the operation performance of the control device 1010 may be substantially prevented from being degraded due to a defect or performance degradation of the cell included in the path through which the signal is transmitted in the control device 1010.

The control device 1010 may adjust or correct signal distortion through analysis of the path through which a signal is transmitted within the control device 1010, or may adjust or correct signal distortion through analysis of the path through which a signal is transmitted from the inside of the control device 1010 to the outside of the control device 1010, or from the outside of the control device 1010 to the inside of the control device 1010. In addition, in some cases, the control device 1010 may change or adjust the setting of the parameter value of a cell included in the path transmitting a signal within the memory device 1020 through cell-by-cell signal measurement and analysis of the signal transmission path within the memory device 1020.

The distortion of a signal transmitted within the control device 1010 or the memory device 1020 included in the data storage system 1000 may be adjusted or corrected in advance by the signal analysis system 100 described above. In addition, in some cases, the signal distortion occurring during the operation of the control device 1010 may be adjusted or corrected by the signal analysis circuit 1012 mounted on the control device 1010.

According to the embodiments of the present disclosure, by adjusting the parameter values of a cell or replacing a cell with redundancy cell(s) through signal measurement and analysis of cells in a signal path (e.g., a signal path 210 in FIG. 1) included in a semiconductor device (e.g., a semiconductor device 200 in FIG. 1, the control device 1010 in FIG. 9), it is possible to prevent or reduce a signal distortion and a performance degradation of the semiconductor device due to signal distortion.

Although some embodiments of the disclosed technology have been described above for illustrative purposes, those skilled in the art will appreciate that various modifications, additions and substitutions may be made based on what is disclosed or illustrated in the present disclosure.

What is claimed is:

1. A signal analysis system comprising:
a first analyzer configured to provide measurement data on a change in a test signal based on signals acquired from a first connection point and a second connection point among a plurality of connection points, each of the plurality of connecting points being between an adjacent pair of a plurality of cells included in a signal path transmitting the test signal; and
a second analyzer configured to generate an analysis signal modified from the test signal based on the measurement data, calculate at least one duty cycle value of the analysis signal, and provide analysis information capable of adjusting a parameter value of at least one cell located between the first connection point and the second connection point based on the at least one duty cycle value.

2. The signal analysis system of claim 1, wherein the second analyzer generates a first analysis signal for a first section and a second analysis signal for a second section, and
wherein the first section is a section in which a level of the test signal changes from a first level to a second level and from the second level to the first level, and the second section is a section in which the level of the test signal changes from the second level to the first level and from the first level to the second level.

3. The signal analysis system of claim 2, wherein the second analyzer calculates a first duty cycle value in a portion where the test signal changes from the first level to the second level based on the first analysis signal, and a second duty cycle value in a portion where the test signal changes from the second level to the first level based on the first analysis signal, and
wherein the second analyzer calculates a third duty cycle value in a portion where the test signal changes from the second level to the first level based on the second analysis signal and a fourth duty cycle value in a portion where the test signal changes from the first level to the second level based on the second analysis signal.

4. The signal analysis system of claim 3, wherein the second analyzer provides, as the analysis information, at least one duty cycle value in a range other than a preset threshold range among the first duty cycle value, the second duty cycle value, the third duty cycle value, and the fourth duty cycle value.

5. The signal analysis system of claim 4, wherein the second analyzer provides information about a cycle of the analysis signal, phase delay data, and jitter data corresponding to the at least one duty cycle value, as the analysis information.

6. The signal analysis system of claim 1, wherein the second analyzer generates the analysis signal using phase delay data, jitter data, and reference signal period, the phase delay data and the jitter data obtained from the measurement data.

7. The signal analysis system of claim 1, wherein the second analyzer extracts first phase delay data between rising edges of the test signal and second phase delay data between falling edges of the test signal based on the measurement data.

8. The signal analysis system of claim 1, wherein the second analyzer provides test termination information if the analysis signal is different from the test signal and the at least one duty cycle value of the analysis signal is within a preset threshold range.

9. The signal analysis system of claim 1, wherein the first analyzer provides voltage change data and jitter data of the test signal for each of a plurality of cycles.

10. The signal analysis system of claim 1, wherein the first analyzer further provides the measurement data based on at least one signal acquired from at least one connection point located between the first connection point and the second connection point.

11. The signal analysis system of claim 1, wherein the signal path is a path through which at least one of a clock signal or a data signal is transmitted in a controller that controls a memory.

12. The signal analysis system of claim 1, wherein the signal path is a first signal path, and the analysis information provides information capable of adjusting at least one parameter value of at least one cell included in a second signal path that transmits a different type of signal than the test signal.

13. A data storage system comprising:
a memory device; and
a control device configured to control the memory device, and adjust at least one first parameter value of at least one cell located between a first connection point and a second connection point based on signals acquired from the first connection point and the second connection point among a plurality of first connection points, each of the plurality of first connecting points being between an adjacent pair of a plurality of first cells included in a first signal path through which a clock signal is transmitted.

14. The data storage system of claim 13, wherein the control device adjusts at least one second parameter value of at least one cell located between a third connection point and a fourth connection point based on signals obtained from the third connection point and the fourth connection point among a plurality of second connection points, each of the plurality of second connecting points being between an adjacent pair of a plurality of second cells included in a second signal path through which a data signal is transmitted.

15. The data storage system of claim 13, wherein the control device adjusts at least one second parameter value of a plurality of second cells included in a second signal path through which a data signal is transmitted based on the first parameter value.

16. The data storage system of claim 13, wherein the control device generates an analysis signal modified from the clock signal using measurement data based on the acquired signals, calculates at least one duty cycle value using the analysis signal, and selects the at least one cell based on the at least one duty cycle value.

17. The data storage system of claim 13, wherein the control device adjusts at least one of an input voltage to the at least one cell or a ratio of the input voltage to an output voltage from the at least one cell.

18. A control device comprising:
a control circuit configured to control a memory device located outside of the control circuit;
a first signal path including a plurality of first cells and transmitting a first type of signal, a first parameter value of at least first one of the plurality of first cells being different from a second parameter value of at least second one of the plurality of first cells, each of the first and second parameter values indicating at least one of an input voltage to a corresponding one of the plurality of first cells or a ratio of the input voltage to an output voltage from the corresponding one of the plurality of first cells; and
a second signal path including a plurality of second cells and transmitting a second type of signal different from the first type of signal.

19. The control device of claim 18, wherein a plurality of parameter values of the plurality of second cells are set to be constant.

20. The control device of claim 18, further comprising a plurality of redundancy cells corresponding to the plurality of first cells, respectively,
wherein the first signal path includes at least one of the plurality of redundancy cells configured to replace the at least first one of the plurality of first cells.
